(19) United States
(12) Patent Application Publication
(10) Pub. No.: US 2024/0120704 A1
(43) Pub. Date: Apr. 11, 2024

(54) SEMICONDUCTOR LASER DEVICE AND METHOD FOR MANUFACTURING SEMICONDUCTOR LASER DEVICE

(71) Applicant: Mitsubishi Electric Corporation, Tokyo (JP)

(72) Inventors: Hodaka SHIRATAKI, Tokyo (JP); Akitsugu NIWA, Tokyo (JP)

(73) Assignee: Mitsubishi Electric Corporation, Tokyo (JP)

(21) Appl. No.: 18/264,888

(22) PCT Filed: Jun. 14, 2021
(86) PCT No.: PCT/JP2021/022523

§ 371 Date: Aug. 9, 2023

(51) Int. Cl. H01S 5/02255; H01S 5/02253; H01S 5/40

(52) U.S. Cl. CPC H01S 5/02255; H01S 5/02253; H01S 5/4031; H01S 5/0234

(57) ABSTRACT

The semiconductor laser device comprises a substrate, a semiconductor laser element that is disposed on the substrate and integrated into a single chip, a substrate electrode and an electrode that are respectively provided on the side of the substrate and on the opposite side of the substrate in the semiconductor laser element, a mirror to reflect incident laser light in a vertical direction relative to the substrate, second mirrors to reflect incident laser light in a horizontal direction relative to the substrate, and a lens to condense incident laser light.

### TECHNICAL FIELD

The present application relates to a semiconductor laser device and a method for manufacturing the semiconductor laser device.

### BACKGROUND ART

In a conventional semiconductor laser device, light from four active layers integrated into a single chip is extracted in a vertical direction by a polygonal pyramid mirror at the center of the chip (refer to, for example, Patent Document 1).

### CITATION LIST

### Patent Document

Patent Document 1: Japanese Patent Application Laid-Open No. H09-051147

### SUMMARY OF INVENTION

### Problems to be Solved by Invention

In the semiconductor laser device as described above, since it is necessary to dispose emission end faces of the active layer in four directions, end face coating on four faces of chip side faces are required. Therefore, even in a case where the processing of two faces among the four faces of the chip side faces is completed first, the end face coating on the (remaining) two faces after the chip is divided into individual chips is required, and thus a problem arises in that productivity is extremely poor.

The present application discloses a technique for solving the above-described problem, and an object of thereof is to provide a semiconductor laser device that can be manufactured only with end face coating on two faces of the chip side faces in the semiconductor laser device in which light from a plurality of light sources integrated into a single chip can be extracted in a vertical direction.

### Means for Solving Problems

A semiconductor laser device disclosed in the present application includes a substrate, a semiconductor laser element in which a plurality of laser light sources for emitting laser light in a longitudinal direction of the substrate are disposed in parallel, a mirror that is disposed to face the laser light sources and reflects the laser light emitted from the laser light sources in a direction orthogonal to a surface of the substrate, and a lens that is disposed adjacent to the mirror and disposed on a side where the laser light reflected by the mirror travels.

### Advantageous Effect of Invention

According to the semiconductor laser device disclosed in the present application, it is possible to provide a semiconductor laser device that can be manufactured only with coating on two end faces of two faces of the chip side faces in the semiconductor laser device in which light from a plurality of light sources integrated into a single chip can be extracted in a vertical direction.

### BRIEF DESCRIPTION OF THE DRAWINGS

FIG. 1 is a top view showing a semiconductor laser device according to Embodiment 1.

FIG. 2 is a partial enlarged view of FIG. 1.

FIG. 3 is a cross-sectional view showing the semiconductor laser device according to Embodiment 1.

FIG. 4 is a cross-sectional view showing the semiconductor laser device according to Embodiment 1.

FIG. 5 is a cross-sectional view showing the semiconductor laser device according to Embodiment 1.

FIG. 6 is a cross-sectional view showing the semiconductor laser device according to Embodiment 1.

FIG. 7 is a cross-sectional view showing the semiconductor laser device according to Embodiment 1.

FIG. 8 is a top view showing a semiconductor laser device according to Embodiment 2.

FIG. 9 is a cross-sectional view showing the semiconductor laser device according to Embodiment 2.

FIG. 10 is a cross-sectional view showing the semiconductor laser device according to Embodiment 2.

FIG. 11 is a cross-sectional view showing the semiconductor laser device according to Embodiment 2.

FIG. 12 is a top view showing a semiconductor laser device according to Embodiment 3.

FIG. 13 is a cross-sectional view showing the semiconductor laser device according to Embodiment 3.

FIG. 14 is a cross-sectional view showing the semiconductor laser device according to Embodiment 3.

FIG. 15 is a cross-sectional view showing the semiconductor laser device according to Embodiment 3.

FIG. 16 is a cross-sectional view showing the semiconductor laser device according to Embodiment 3.

FIG. 17 is a cross-sectional view showing the semiconductor laser device according to Embodiment 1 to Embodiment 3.

FIG. 18 is a top view and a cross-sectional view showing a semiconductor laser device according to Embodiment 4.

FIG. 19 is an explanatory diagram for a process when end face coating is performed in the semiconductor laser device according to Embodiment 1.

FIG. 20 is an explanatory diagram for a case where end face coating is performed using a jig in the semiconductor laser device according to Embodiment 1.

### MODE FOR CARRYING OUT INVENTION

The present application relates to a semiconductor laser device including mirrors for changing a traveling direction of light, a lens, and a plurality of active layers. Hereinafter, specific embodiments of the semiconductor laser device will be described with reference to the figures.

### Embodiment 1

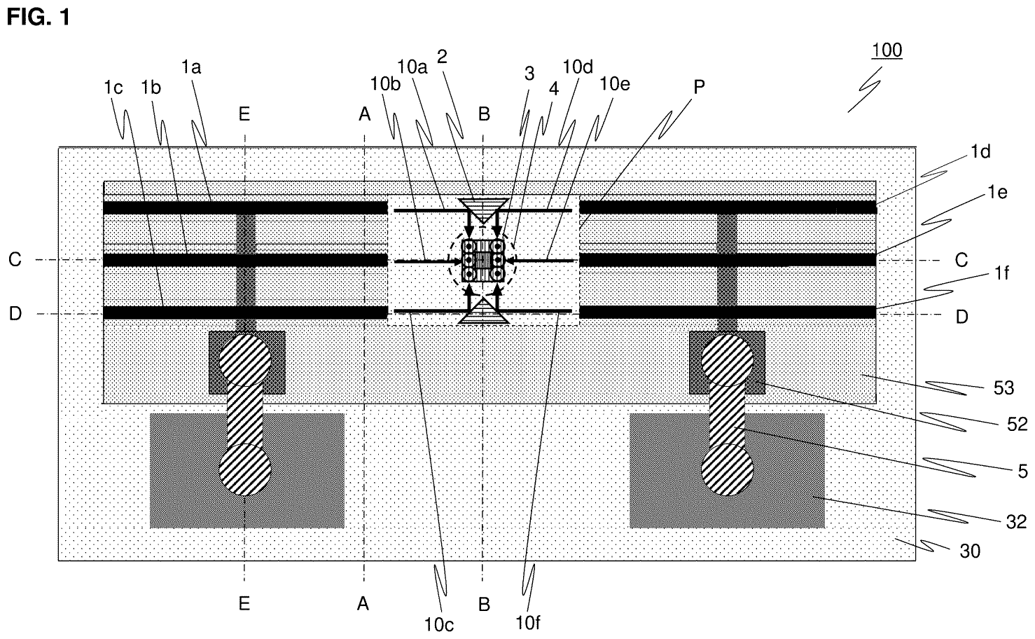

A semiconductor laser device 100 according to Embodiment 1 will be described in detail below with reference to FIG. 1 to FIG. 7.

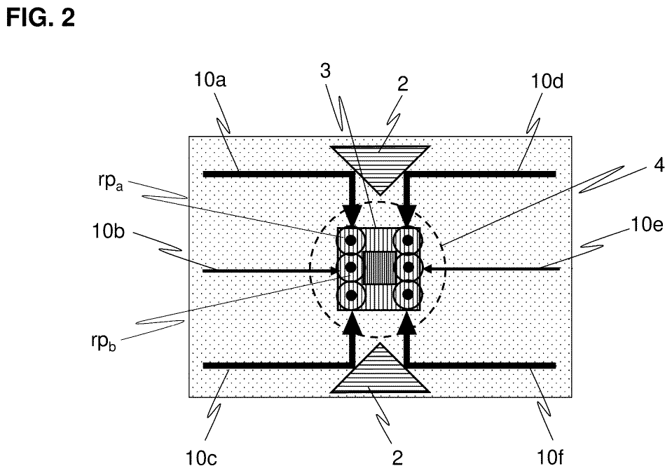

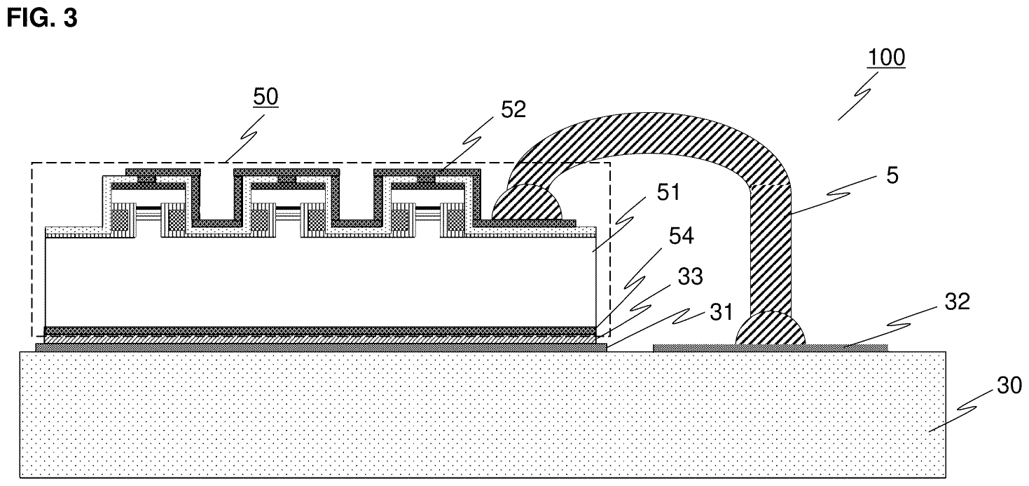

Further, FIG. 2 is an enlarged view of a central portion P of the semiconductor laser device 100 shown in FIG. 1. In addition, FIG. 3 is a cross-sectional view taken along the line E-E in FIG. 1. Hereinafter, a schematic configuration of the semiconductor laser device 100 according to Embodiment 1 will be described first with reference to these figures.

As can be seen from FIG. 3, in the semiconductor laser device 100, regarding the thickness direction, a submount 30 is disposed on the entire lower side thereof and the semiconductor laser element 50 (corresponding to a portion surrounded by a dotted line in FIG. 3) bonded with solder 33 via a submount electrode 31 in contact with the submount 30 is disposed on the upper side. The semiconductor laser element 50 includes an optical system constituted by mirrors and a lens that is disposed in the central portion P described above (refer to FIG. 1), a plurality of light sources disposed in a peripheral portion of the optical system, and a substrate 51 on which the optical system and the light sources described above are disposed (these components will be described in detail below). The semiconductor laser element 50 is connected to a submount electrode 32 via a wire 5, the submount electrode being separated from the above-described submount electrode 31 and being disposed at a different position on the submount 30.

Here, the submount 30 is made of aluminum nitride (AlN), the submount electrodes 31 and 32 formed on the submount 30 are made of Au, the solder 33 is made of Sn/Ag, and the wire 5 is made of Au.

Note that each material to be used is such that the submount 30 may be made of a ceramic material such as alumina (Al₂O₃), the submount electrodes 31 and 32 may be made of a conductive material such as Cu, Pt, or Si, the solder 33 may be made of a lead-free solder such as Sn/Ag/Cu, Sn/Ag/Bi/In, Sn/Ag/Cu/Ni/Ge, Sn/Bi, Sn/Bi/Ag, or Sn/Bi/Cu, and the wire 5 may be made of a metallic material such as an Au-alloy, Cu, Al, or Ag.

Next, a trajectory (light path) of laser light of the semiconductor laser device 100 according to Embodiment 1 will be described with reference to FIG. 1 and FIG. 2. Here, in particular, using the light sources 1a and 1b shown in FIG. 1 as a representative example, trajectories (light paths) of the laser light emitted from six light sources 1a to 1f included in the semiconductor laser device 100 will be described first. Note that, in FIG. 1, both ends of the wire 5 are connected to an electrode 52 and the submount electrode 32. Further, two electrodes 52 arranged on the left and right sides of the figure are disposed on an insulating film 53 in common to be described later.

The traveling direction of the light emitted from the light sources 1a to 1f is changed in a left and right direction (hereinafter, also referred to as a longitudinal direction) or in a direction perpendicular to the paper surface in the semiconductor laser device 100 shown in FIG. 1 by using the optical system constituted by the mirrors and the lens (here, a lens having a function as a condensing lens) disposed on the central portion P. Note that the optical system is disposed in line symmetry with respect to the center line in the shape of the semiconductor laser device 100, that is, the line B-B for a cross section corresponds to the center line in the shape. In addition, a light source group 1a to 1c and a light source group 1d to 1f are also disposed substantially in line symmetry to each other with respect to the center line in the shape.

To be specific, the light emitted from the light source 1a reaches a 45-degree-angle triangular prism-shaped horizontal direction mirror 2 (Hereinafter, also referred to as a second mirror. The center line in the shape of the semiconductor laser device 100 shown in FIG. 1, here the B-B line, is the line corresponding to the center line in the shape of the second mirror.), is reflected by the surface thereof, is bent by about 90 degrees as the traveling direction, and travels toward the direction of a 45-degree-angle vertical direction mirror 3 (hereinafter, simply referred to as a mirror) that is in a truncated square pyramid shape and disposed in the central portion of the semiconductor laser element 50 (refer to a light path 10a in FIG. 1 and FIG. 2). The light that reaches the 45-degree-angle vertical direction mirror 3 is reflected by an inclined surface having an inclination angle of 45 degrees with respect to the substrate among surfaces of the 45-degree-angle vertical direction mirror 3, and then passes through a hemispherical lens 4 to travel in the front direction (a direction perpendicular to the paper surface) of FIG. 1 and FIG. 2 (refer to a reflection point rpₐ in FIG. 2).

Next, the light emitted from the light source 1b directly reaches the 45-degree-angle vertical direction mirror 3 disposed on the central portion of the semiconductor laser element 50 without passing through the 45-degree-angle triangular prism-shaped horizontal direction mirror 2, is reflected by the above-described inclined surface of the 45-degree-angle vertical direction mirror 3 in the truncated square pyramid shape, passes through the hemispherical lens 4, and is emitted toward the front direction (the direction perpendicular to the paper surface) of FIG. 1 and FIG. 2 (refer to a light path 10b in FIG. 1 and FIG. 2 and a reflection point rp_{b} in FIG. 2).

The light emitted from the light sources 1c, 1d, and 1f travel along similar light paths as the light emitted from the light source 1a (refer to the respective light paths 10c, 10d, and 10f in FIG. 1 and FIG. 2), and the light emitted from the light source 1e travels along a similar light path as the light emitted from the light source 1b described above (refer to the light path 10e in FIG. 1 and FIG. 2).

In the above description, the optical system is disposed in line symmetry with respect to the center line in the shape of the semiconductor laser device 100. Here, the line B-B for the cross section is the line corresponding to the center line in the shape. In addition, the light source group 1a to 1c and the light source group 1d to 1f are also disposed substantially in line symmetry to each other with respect to the center line in the shape.

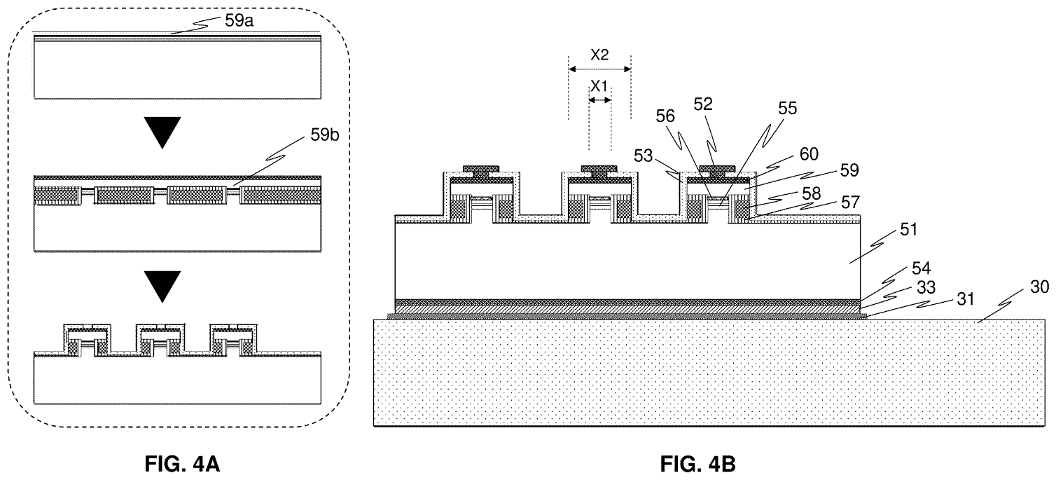

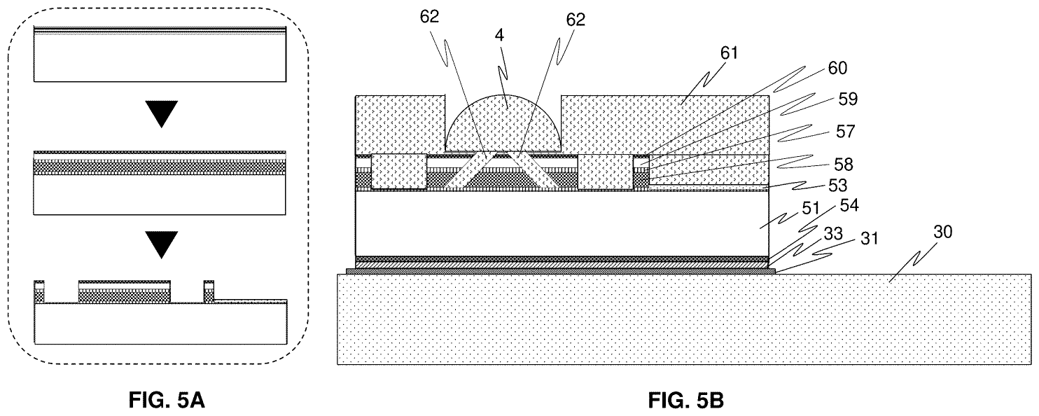

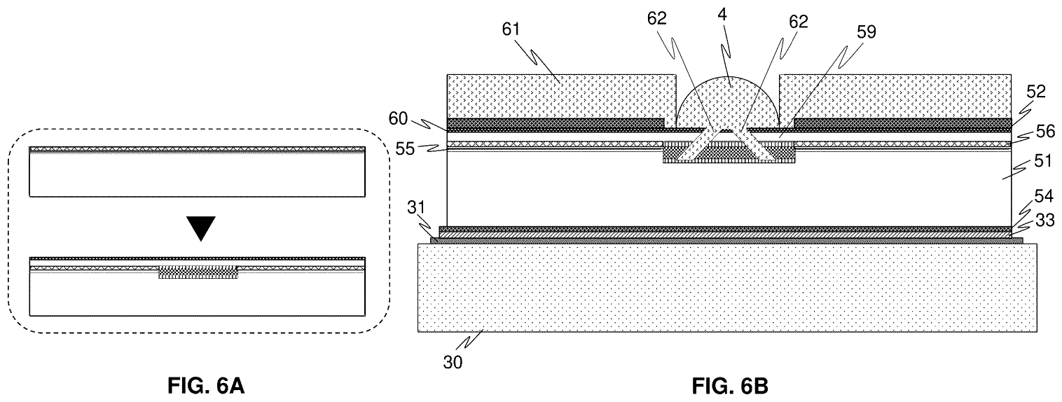

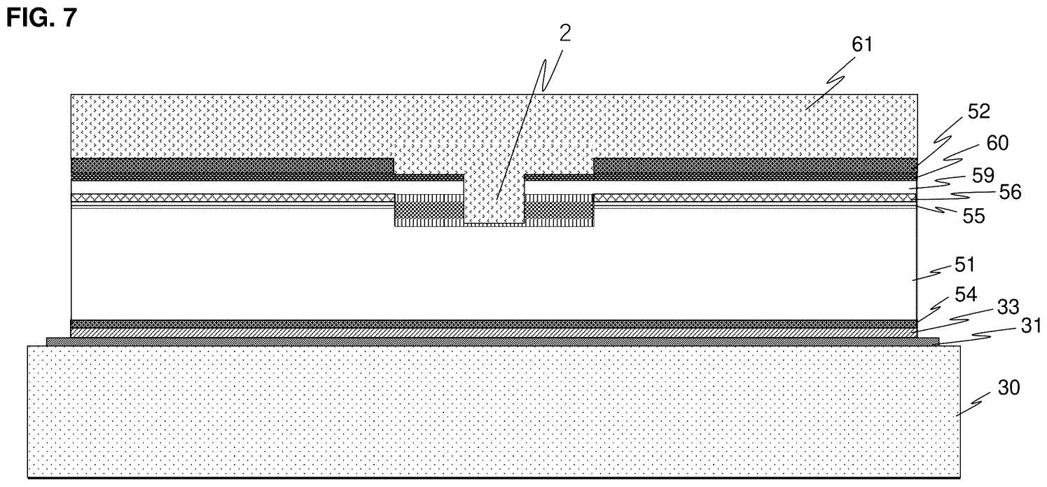

Next, a detailed structure of the semiconductor laser device having the light paths as described above will be described with reference to cross-sectional views of a plurality of portions thereof on the basis of FIG. 1. Here, descriptions will be made in order below on the basis of a cross-sectional view (FIG. 4B) showing an A-A cross section, a cross-sectional view (FIG. 5B) showing a B-B cross section, a cross-sectional view (FIG. 6B) showing a C-C cross section, and a cross-sectional view (FIG. 7) showing a D-D cross section with reference to FIG. 1.

First, a detailed structure of the semiconductor laser element 50 will be described with reference to FIG. 4. FIG. 4 is composed of two figures: FIG. 4A is a schematic view of a manufacturing process of the semiconductor laser element in which the overview thereof is shown separately in three steps surrounded by a dotted line frame on the left side of the figure, and FIG. 4B is a cross-sectional view taken along the line A-A of FIG. 1 on the right side of the figure, is a configuration in the case where the semiconductor laser element 50 is disposed on the submount 30, and is a configuration diagram for describing the details of components of the semiconductor laser element.

In FIG. 4B described above, the semiconductor laser element 50 includes an substrate 51 made of InP, an active layer 55 made of InGaAsP and formed on the substrate 51, a diffraction grating 56 made of InGaAsP and formed on the active layer 55, a blocking layer 57 made of p-InP and a blocking layer 58 made of n-InP that are formed on a side area of the substrate 51, the active layer 55, and the diffraction grating 56, an cladding layer 59 made of InP and formed on the p-InP blocking layer 57, a contact layer 60 made of InGaAs and formed on the cladding layer 59, an insulating film 53 made of SiN and formed on the contact layer 60, an electrode 52 made of Au and formed in a portion in which the contact layer 60 is exposed in an opening of the insulating film 53, and a substrate electrode 54 made of Au and formed on the opposite side facing the active layer.

Each material to be used instead of the materials described above is such that the substrate 51 described above may be made of GaAs, the active layer 55 above may be made of AlGaInAs, GaInAsP, or the like, the blocking layer 57 above may be made of Fe—InP, etc., the insulating film 53 above may be made of SiO₂, or the like, and the electrodes 52 and the substrate electrodes 54 above may be made of Pt, Ag, Cu, etc.

Next, a detailed structure of the semiconductor laser element 50 will be described with reference to FIG. 5. FIG. 5 is composed of two figures: FIG. 5A is a schematic view of a manufacturing process of the semiconductor laser element in which the overview thereof is shown separately in three steps surrounded by a dotted line frame on the left side of the figure, and FIG. 5B is a cross-sectional view taken along the line B-B of FIG. 1 on the right side of the figure, is a configuration in the case where the semiconductor laser element 50 is disposed on the submount 30, and is a configuration diagram for describing the details of components of the semiconductor laser element.

In FIG. 5B described above, the semiconductor laser element 50 includes the substrate electrode 54, the substrate 51, a multilayer sandwich structure constituted by the p-InP blocking layer 57, the n-InP blocking layer 58, and the p-InP blocking layer 57 formed on the substrate, the above-described cladding layer 59 formed on the p-InP blocking layer 57, the contact layer 60 formed on the cladding layer 59, the insulating film 53 formed on the p-InP blocking layer 57 except for a portion in and around the lens, a photosensitive acrylic resin 61 formed so as to fill and flatten unevenness of the substrate, and the hemispherical lens 4 formed by processing the photosensitive acrylic resin 61.

Next, a detailed structure of the semiconductor laser element 50 will be described with reference to FIG. 6. FIG. 6 is composed of two figures: FIG. 6A is a schematic view of a manufacturing process of the semiconductor laser element in which the overview thereof is shown separately in three steps surrounded by a dotted line frame on the left side of the figure, and FIG. 6B is a cross-sectional view taken along the line C-C of FIG. 1, shown on the right side of the figure, is a configuration in the case where the semiconductor laser element 50 is disposed on the submount 30, and is a configuration diagram for describing the details of components of the FIG. 6B is a cross-sectional view taken along the line C-C in FIG. 1. In the semiconductor laser element 50, the portion in and around the lens 4 has the same cross section as that in FIG. 5B, and the other portion have the same cross section as that inside the range indicated by X1 in FIG. 4B.

Lastly, FIG. 7 shows a cross-sectional view taken along the line D-D in FIG. 1. In the semiconductor laser element 50, the portion in and around the lens 4 has the same cross section as in the case of FIG. 5B, and the other portion has the same cross section as that inside the range indicated by X1 in FIG. 4B.

Next, an example of a method for manufacturing the semiconductor laser element 50 will be described below with reference to the figures. After the active layer 55 and the diffraction grating 56 are formed on the substrate 51 by epitaxial growth, these layers formed are buried with a cladding layer 59a as shown in FIG. 4A. A region other than a range (size in 0.5 to 2 μm) for a waveguide portion indicated by the symbol X1 in FIG. 4B is dry-etched to the layer of the substrate 51 disposed below the active layer 55, the sandwich structure constituted by three blocking layers of the p-InP blocking layer 57, the n-InP blocking layer 58, and the p-InP blocking layer 57 is buried in the dry-etched region by epitaxial growth, and another cladding layer 59b is formed on the cladding layer 59a and the blocking layer by epitaxial growth. Further, after the contact layer 60 is formed on the cladding layer 59b by epitaxial growth, the blocking layer 57 made of p-InP is etched until the blocking layer 57 is completely removed except for a portion in a range (size in 8 to 30 μm) indicated by X2. At this time, by performing etching at the same time, the 45-degree-angle triangular prism-shaped horizontal direction mirror 2 shown in FIG. 7 is also fabricated.

Next, a trench 62 shown in FIG. 5B and FIG. 6B is formed at an angle of 45 degrees with respect to the upper surface by anisotropic etching using ClF₃ gas clusters, and thus the 45-degree-angle vertical direction mirror 3 in the truncated square pyramid shape is formed. After the insulating film 53 is formed by a chemical vapor deposition (CVD) method, the insulating film 53 only above the waveguide is removed by dry etching, and then the electrode 52 is formed in an opening of the insulating film 53 by a sputtering method.

By applying the photosensitive acrylic resin 61 by spin coating, the trench 62 is filled with the photosensitive acrylic resin 61 and the surface is planarized. The photosensitive acrylic resin 61 in an electrode pad portion is removed by a developing process. The lens 4 is formed by applying a gray scale lithography process to the photosensitive acrylic resin 61 on the upper part of the 45 degree-angle vertical direction mirror 3 that is in the truncated square pyramid shape. Lastly, the substrate electrode 54 is formed by a sputtering method.

In the above description, the photosensitive acrylic resin 61 is used for the filling of the trench 62 and the planarization process of the surface, but other materials may be used as long as the critical angle of total reflection is 45 degrees or less (refractive index of 2.3 or less) when the material on which light is incident is InP. It is also possible to use another anisotropic etching method for forming the trench 62. It is also possible to form the insulating film 53 by a sputtering method or the like, or to form the electrode 52 and the substrate electrode 54 by a vapor deposition method.

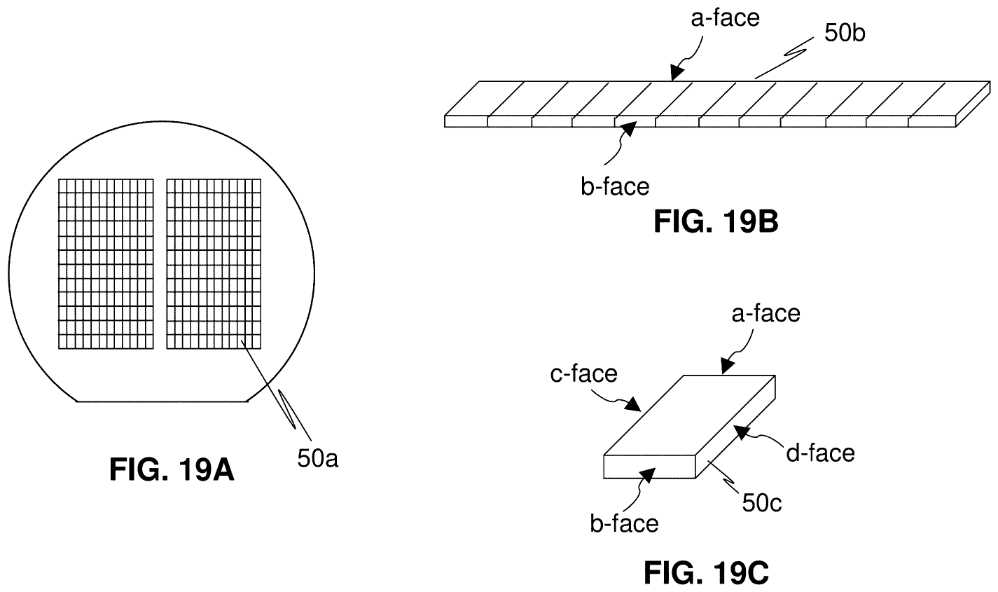

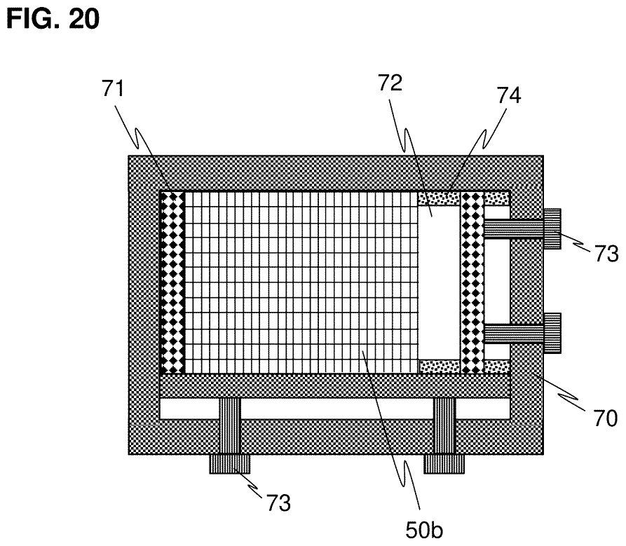

Next, a method of separating the semiconductor laser element 50 manufactured by the wafer process of the semiconductor laser device of Embodiment 1 into individual chips and coating end surfaces of the chips will be described with reference to FIG. 19 and FIG. 20. FIG. 19 is composed of FIG. 19A, FIG. 19B, and FIG. 19C for describing the process of end face coating.

Here, FIG. 19A is a diagram showing a semiconductor laser element 50a in a wafer state, FIG. 19B is a diagram showing the semiconductor laser element 50b processed into a bar state (also referred to as a semiconductor laser element 50b in a bar state), and FIG. 19C is a diagram showing a semiconductor laser element 50c in a chip state. In addition, FIG. 20 is a view seen from the front side (the front side in the direction perpendicular to the paper plane, the same applies hereinafter) when the semiconductor laser element 50 is arranged on a jig, and a diagram in which, after the semiconductor laser element is processed into each of the semiconductor laser element 50b in the bar state, a-faces in the semiconductor laser element is arranged on the front side in the diagram for the coating of the a-faces and b-faces (both end faces in the longitudinal direction in a chip state each correspond to the a-face and the b-face).

The semiconductor laser element is processed from the wafer state (refer to FIG. 19A) to the bar state (refer to FIG. 19B) by a cleavage process. A plurality of the semiconductor laser elements 50b in the bar state are arranged using a jig 70 shown in FIG. 20 such that the a-faces are in the front side and the b-faces are in the rear side (back side in the direction perpendicular to the paper surface), and with both sides of the arranged elements sandwiched by Si dummy bars 71, they are fixed using a bar end setting portion 74 provided in the jig by adjusting with a plurality of adjusting screws 73 vertically and horizontally until a cavity 72 is eliminated. The reason why the Si dummy bars are used as dummy bars is that the Si material does not cause strain that occurs in metallic materials, so that no local stress is applied to the semiconductor laser element when it is tightened with a jig, the Si material is a stable material whose state does not change at all times because a natural oxide film is formed on the surface, and the Si material has little surface unevenness. When the end face coating of the semiconductor laser element is performed, a film is formed by a sputtering method on each of the front and rear faces of the (entire) semiconductor laser elements 50b in the bar state arranged for each jig, thereby forming the coating with desired reflectance in which Si, SiO₂, and Al₂O₃ are laminated on each of the a-face and the b-face. After the a-face and the b-face are coated, the laser elements are separated into a chip state shown in FIG. 19C.

Since the end face coating in the semiconductor laser device of Embodiment 1 is performed on only two faces of the a-face and the b-face, the process therefor can be completed up to the step of the end face coating (also, referred to as end face coat) in the bar state as described above. In contrast, in the device of Patent Document 1, it is necessary to coat all of the four end faces (a-face, b-face, c-face, and d-face) of one chip shown in FIG. 19C. For example, after coating the end faces of the a-faces and the b-faces in a bar state, the elements are processed into a chip state, and further it is necessary to coat the c-face and the d-face of each of the processed chips.

As described above, according to the semiconductor laser device of Embodiment 1, the light path is changed to the direction perpendicular to the resonator by the mirrors that reflect light in the horizontal direction with respect to the substrate, the light is collected at the central portion of the substrate, and the light collected at the central portion of the substrate is reflected in the vertical direction with respect to the substrate by the mirror that reflects light in the vertical direction with respect to the substrate. Thus, four to six types of light in a bundle can be extracted in the vertical direction with respect to the substrate. Therefore, it is possible to provide a semiconductor laser device which can be manufactured only with the coating on the two end faces of the side faces of the chip.

Furthermore, the bundled light using the mirrors for reflecting the light in the horizontal direction with respect to the substrate and the mirror for reflecting the light in the vertical direction with respect to the substrate can be extracted as combined light, and thus coupling with an external optical fiber is facilitated.

### Embodiment 2

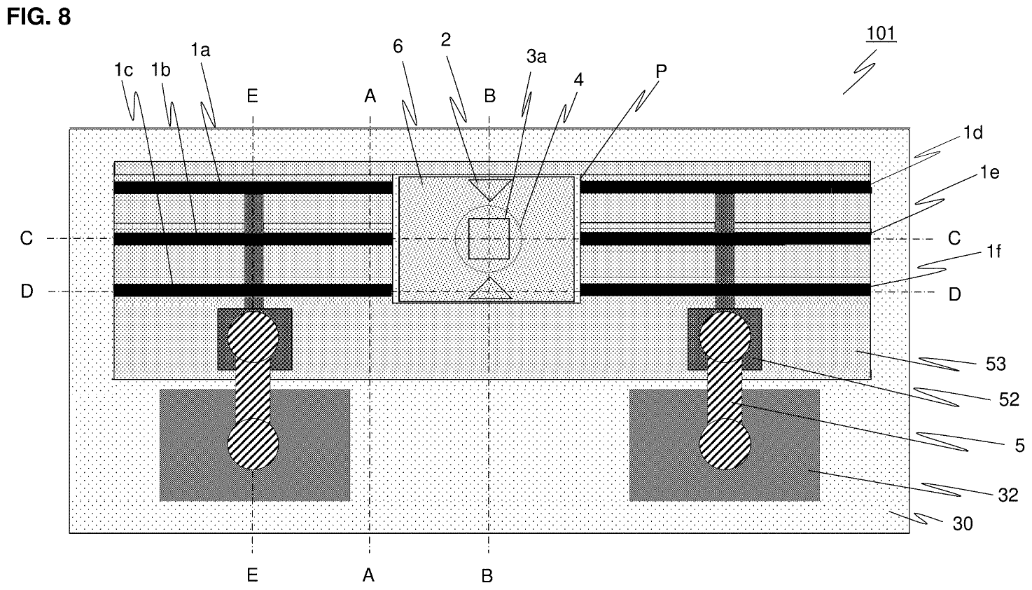

A semiconductor laser device 101 according to Embodiment 2 will be described in detail below with reference to FIG. 8 to FIG. 11.

FIG. 8 is a top view of the semiconductor laser device according to Embodiment 2. The 45-degree-angle vertical direction mirror 3 in the truncated square pyramid shape in Embodiment 1 is replaced with a 45-degree-angle vertical direction mirror 3a in a square pyramid shape, and an Al coating 6 is applied to the surfaces of the 45-degree-angle vertical direction mirror 3a in a square pyramid shape and the 45-degree-angle triangular prism-shaped horizontal direction mirror 2. Since the structure of the semiconductor laser element 50 in and around the lens 4 is different from that of Embodiment 1, it will be described with reference to cross-sectional views.

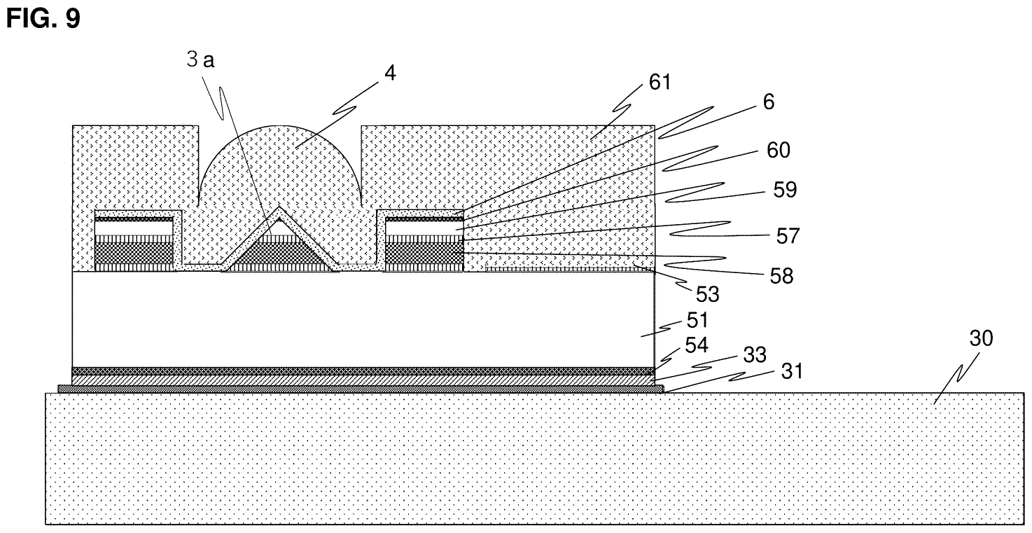

FIG. 9 is a cross-sectional view taken along the line B-B in FIG. 8. The semiconductor laser element 50 is different in the processed shape from that in the substrate shown in FIG. 5B in Embodiment 1, and the Al coating 6 is applied to the surface after the process.

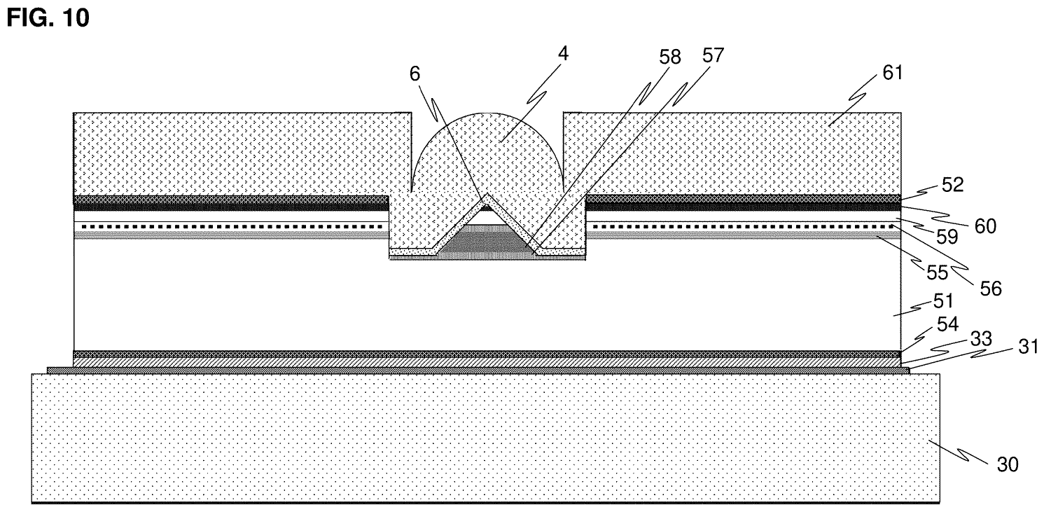

FIG. 10 is a cross-sectional view taken along the line C-C in FIG. 8. The semiconductor laser element 50 has a similar cross section as that of FIG. 9 in and around the lens and has a similar cross section as that inside the range X1 in FIG. 4B in Embodiment 1 in the other portion.

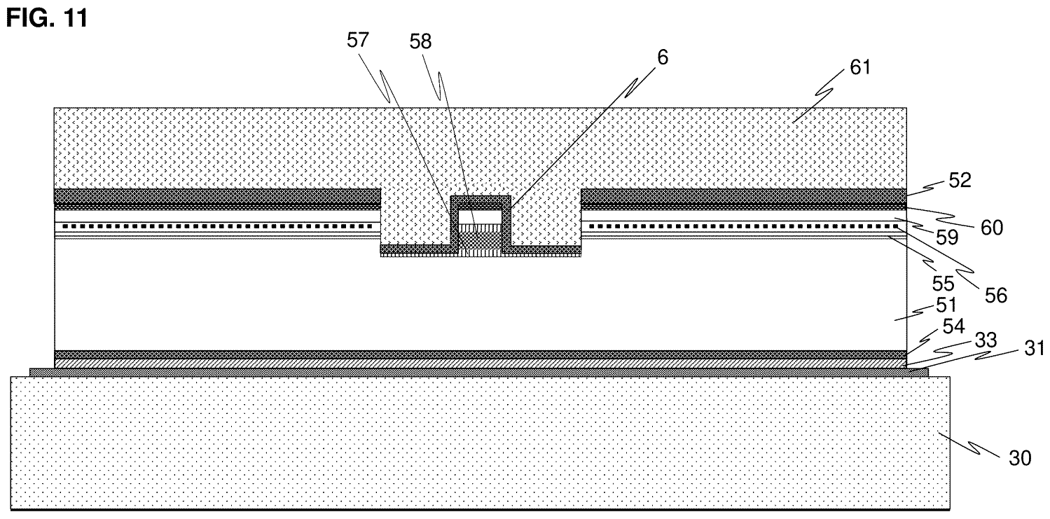

FIG. 11 is a cross-sectional view taken along the line D-D in FIG. 8. The semiconductor laser element 50 has a similar cross section as that of FIG. 9 in and around the lens and has a similar cross section as that inside the range X1 in FIG. 4B in Embodiment 1 in the other portion.

In the present embodiment, the Al coating 6 is applied to the surfaces of the 45-degree-angle vertical direction mirror 3a and the 45-degree-angle triangular prism-shaped horizontal direction mirror 2. In the case of a semiconductor laser element that is not required to have a high optical output, since there is no problem even with a structure that cannot induce the total reflection, the same effect can be obtained even if the Al coating 6 is no applied thereto.

As described above, according to the semiconductor laser device of Embodiment 2, in a case where a material having a refractive index that cannot induce the total reflection is used to form a mirror, light can be reflected with a low loss.

### Embodiment 3

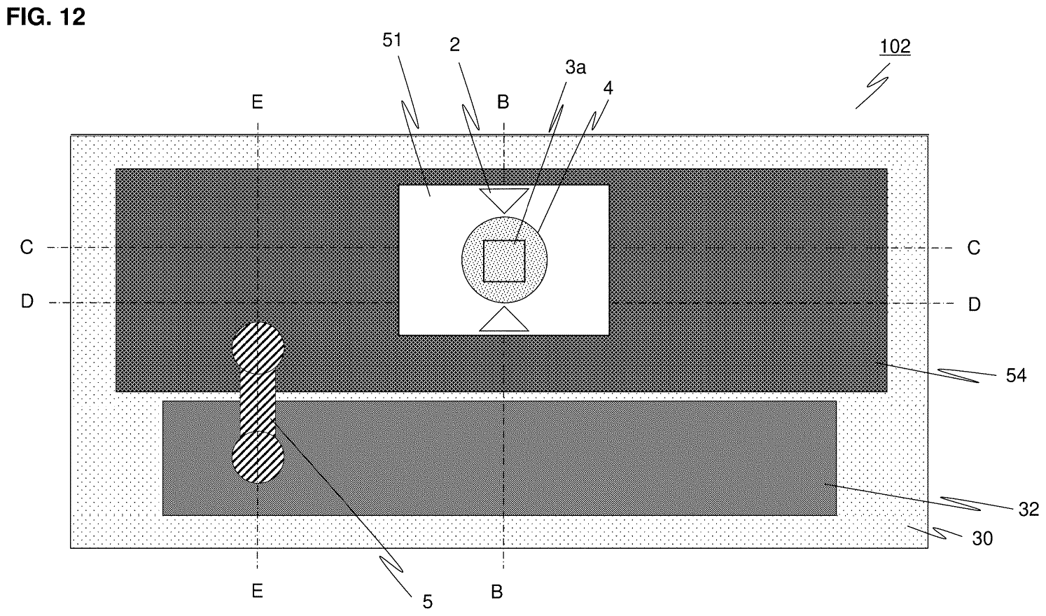

A semiconductor laser device according to Embodiment 3 will be described below in order with reference to FIG. 12 to FIG. 16.

First, FIG. 12 is a top view of a semiconductor laser device 102 according to Embodiment 3. The 45-degree-angle vertical direction mirror 3a and the 45-degree-angle triangular prism-shaped horizontal direction mirror 2 of Embodiment 2 are formed in a recessed shape by etching with respect to a semiconductor laser element 50, and the Al coating 6 is not applied thereto. The lens 4 is formed on the rear side of the semiconductor laser element 50, and the electrode on the side of the active layer 55 of the semiconductor laser element 50 is used for die bonding in a junction down method. Therefore, the structure of the semiconductor laser element 50 in and around the lens 4, which is different from that of Embodiment 2, will be described below with reference to cross-sectional views.

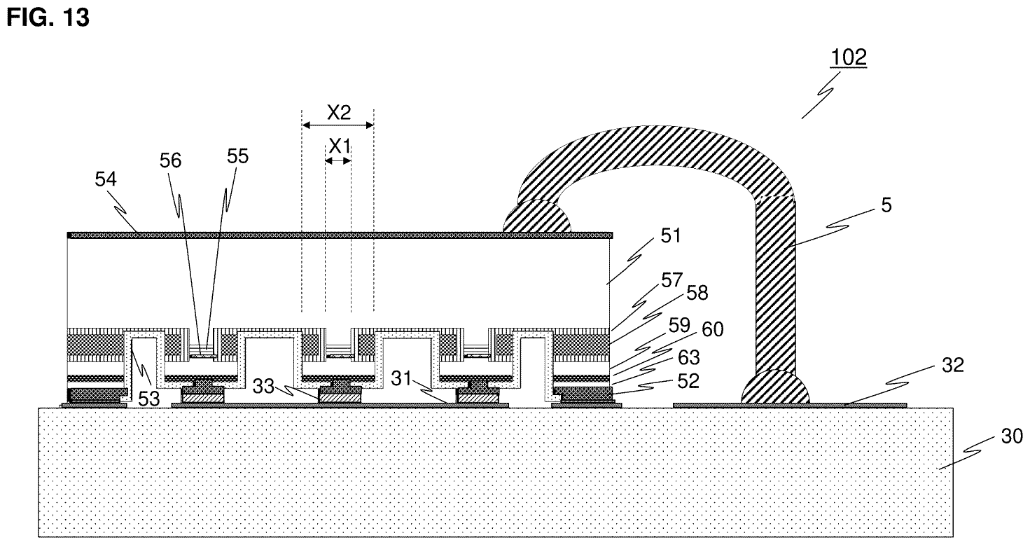

Next, FIG. 13 shows a cross-sectional view taken along the line E-E in FIG. 12. In the semiconductor laser element 50, in contrast to FIG. 4B of Embodiment 1, the outer peripheral portion of the substrate remains without being etched, and a cushion layer 63 is formed on the contact layer 60 in the outer peripheral portion of the substrate. This is for the purpose of reducing thermal stress applied to the active layer 55 at the time of die bonding by the junction down method.

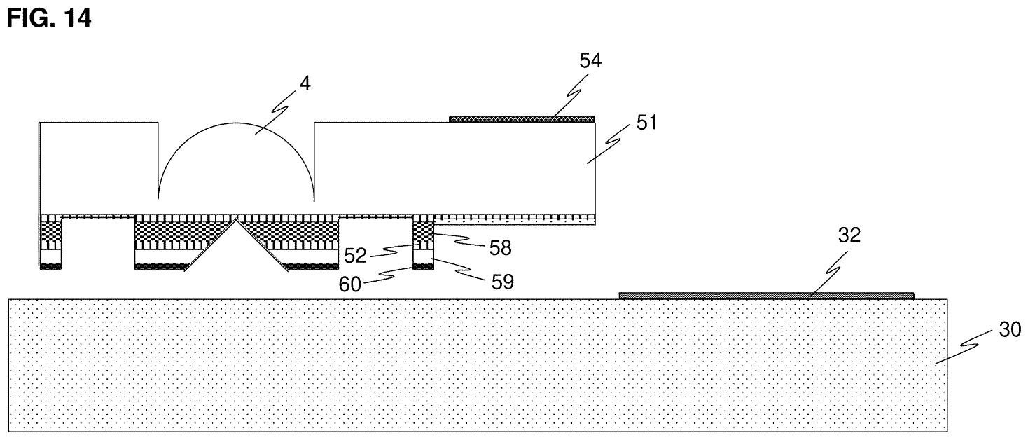

Next, FIG. 14 is a cross-sectional view taken along the line B-B in FIG. 12. In the semiconductor laser device 50, the processed shape of the unevenness of the substrate is reversed from that in FIG. 9 of Embodiment 2, and the Al coating 6 and the photosensitive acrylic resin 61 are not present. Further, the lens 4 is formed on the opposite side facing the active layer.

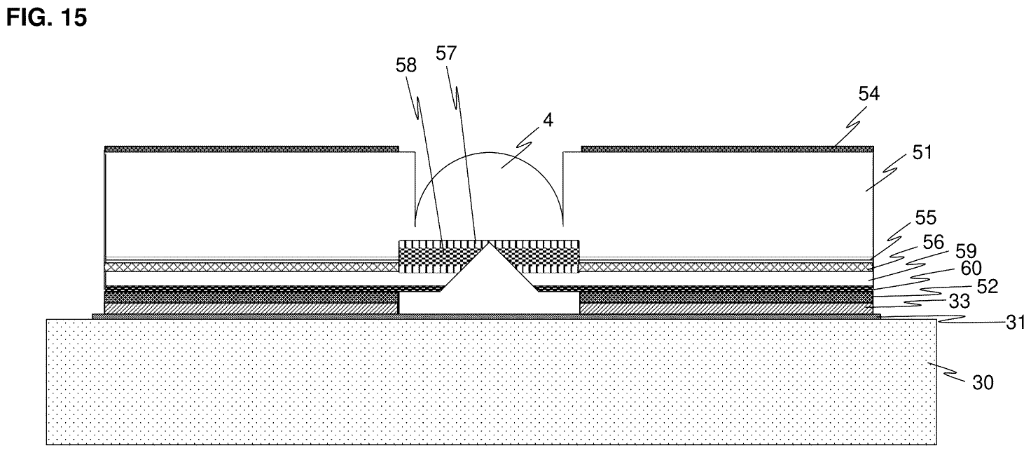

Next, FIG. 15 is a cross-sectional view taken along the line C-C in FIG. 12. The semiconductor laser element 50 has a similar cross section as that of FIG. 14 in and around the lens and has a similar cross section as that inside the region X1 of FIG. 13 in the other portion.

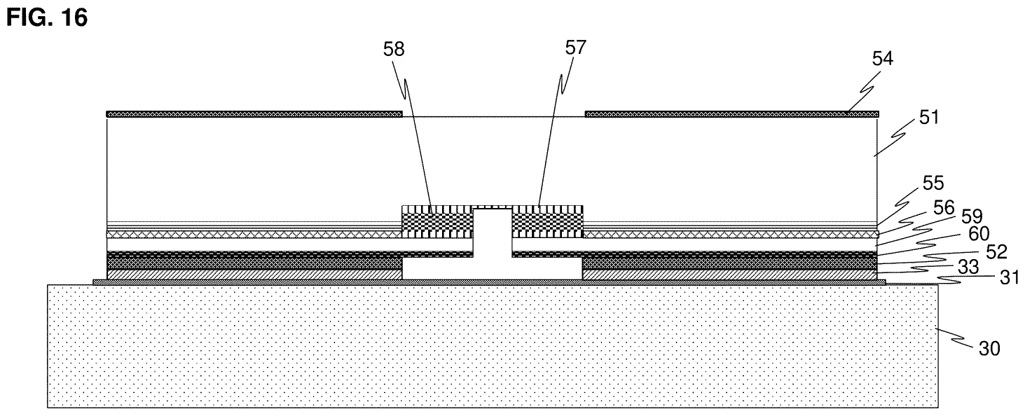

Lastly, FIG. 16 shows a cross-sectional view along D-D in FIG. 12. The semiconductor laser element 50 has a similar cross section as that of FIG. 14 in and around the lens and has a similar cross section as that inside the region X1 of FIG. 13 in the other portion.

As described above, according to the semiconductor laser device of Embodiment 3, since the planarization process for forming the lens is not required, the manufacturing process can be simplified. Further, since the semiconductor laser device has a plurality of light-emitting layers, in which the total amount of current during use is large and the amount of heat generated is large, by using the junction down method, the heat can be efficiently dissipated.

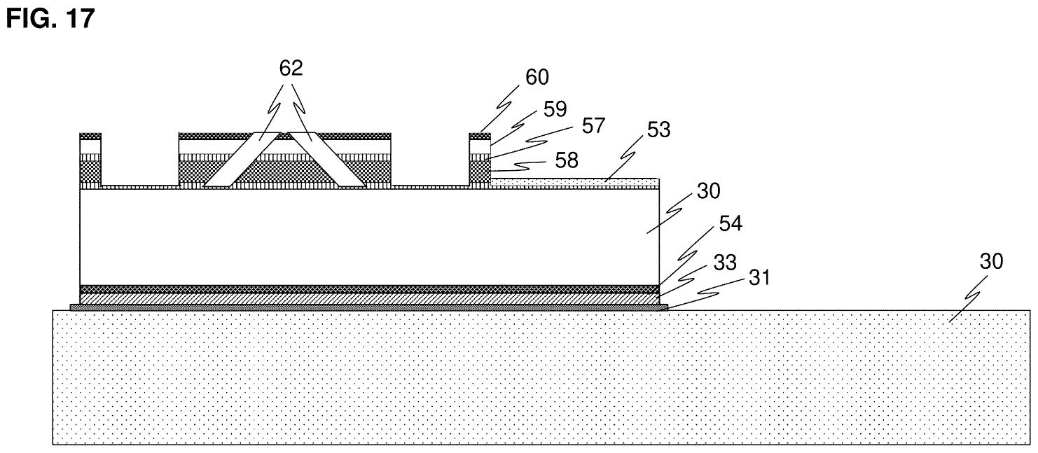

In Embodiment 1, Embodiment 2, and Embodiment 3 described above, the lens 4 is included in the semiconductor laser element 50. However, from the viewpoint of productivity improvement, light combining may be performed by an external lens. In this case, for example, a structure shown in FIG. 17, which is obtained by removing the photosensitive acrylic resin 61 and the lens 4 from the semiconductor laser device shown in FIG. 5B, is also effective.

### Embodiment 4

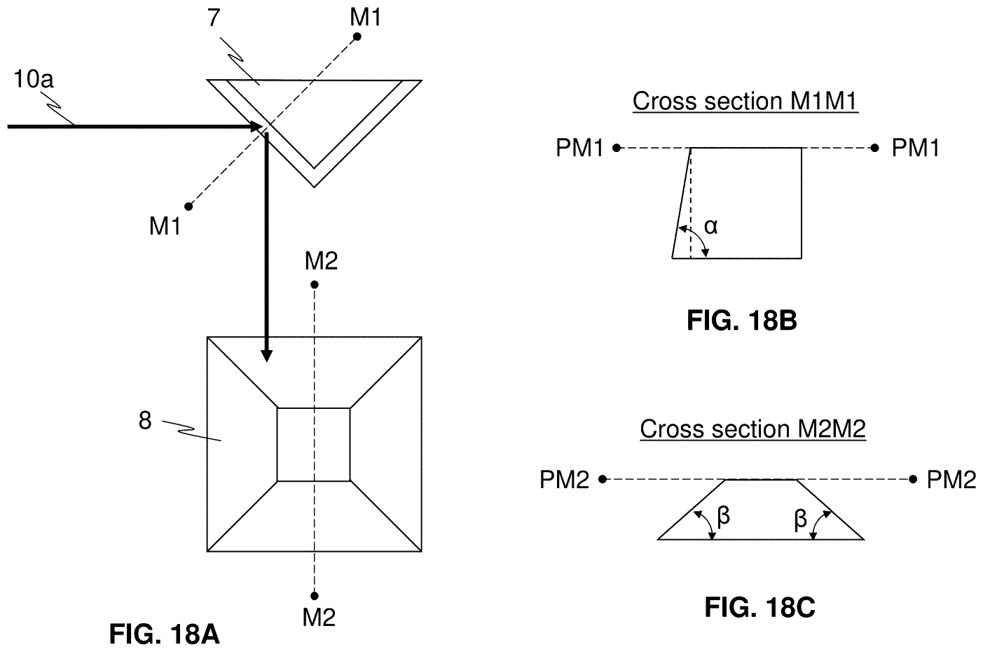

A semiconductor laser device according to Embodiment 4 will be described below with reference to FIG. 18A, FIG. 18B, and FIG. 18C. Here, FIG. 18B is a cross-sectional view taken along the dotted line M1-M1 of FIG. 18A, and FIG. 18C is a cross-sectional view taken along a dotted line M2-M2 of FIG. 18A.

In Embodiment 1, Embodiment 2, and Embodiment 3 described above, the angle in the 45-degree-angle triangular prism-shaped horizontal direction mirror and the 45-degree-angle vertical direction mirror is 45 degrees, which is the most orthodox angle. However, as long as light having an angle of 90 degrees with respect to the substrate is to be finally output (refer to FIG. 2 and FIG. 18A), for example, an inclination angle α of a non-45-degree-angle triangular prism-shaped horizontal direction mirror 7 (also referred to as a third mirror 7) with respect to the substrate may be formed to be 80 degrees as shown in 18A and 18B, and an inclination angle β of a non-45-degree-angle vertical direction mirror 8 (also referred to as a fourth mirror 8) with respect to the substrate may be formed to be 35 degrees as shown in 18A and 18C.

Although various exemplary embodiments and examples are described in the present application, various features, aspects, and functions described in one or more embodiments are not inherent in a particular embodiment and can be applicable alone or in their various combinations to each embodiment. Accordingly, countless variations that are not illustrated are envisaged within the scope of the art disclosed herein. For example, the case where at least one component is modified, added or omitted, and the case where at least one component is extracted and combined with a component in another embodiment are included. Specifically, for example, the end face coating described in Embodiment 1 is applicable to Embodiment 2 to Embodiment 4 as well.

### DESCRIPTION OF REFERENCE NUMERALS AND SIGNS

1a, 1b, 1c, 1d, 1e, 1f: light sources, 2: 45-degree-angle triangular prism-shaped horizontal direction mirror (second mirror), 3, 3a: 45-degree-angle vertical direction mirror (mirror), 4: lens, 5: wire, 6: Al coating, 7: non-45-degree-angle triangular prism-shaped horizontal direction mirror (third mirror), 8: non-45-degree-angle vertical direction mirror (fourth mirror), 10a, 10b, 10c, 10d, 10e, 10f: light path, 30: submount, 31, 32: submount electrode, 33: solder, 50: semiconductor laser element, 50a: semiconductor laser element in a wafer state, 50b: semiconductor laser element in a bar state, 50c: semiconductor laser element in a chip state, 51: substrate, 52: electrode, 53: insulating film, 54: substrate electrode, 55: active layer, 56: diffraction grating, 57, 58: blocking layer, 59, 59a, 59b: cladding layer, 60: contact layer, 61: photosensitive acrylic resin, 62: trench, 63: cushion layer, 70: jig, 71: Si dummy bar, 72: cavity, 73: adjusting screw, 74: bar end setting portion, 100, 101, 102: semiconductor laser device

1. A semiconductor laser device comprising:
a substrate;
a semiconductor laser element including a plurality of laser light sources that are disposed in a longitudinal direction of the substrate in parallel and all of which emit laser light in the longitudinal direction of the substrate;
a mirror that is disposed to face the laser light sources and reflects the laser light emitted from the laser light sources in a direction orthogonal to a surface of the substrate; and
a lens that is disposed adjacent to the mirror on the same side of the semiconductor laser element relative to the substrate and disposed on a side where the laser light reflected by the mirror travels.

2. (canceled)

3. The semiconductor laser device according to claim 1, wherein the mirror has a truncated square pyramid shape or a polygonal pyramid shape and has surfaces inclined at 45 degrees with respect to the substrate.

4. The semiconductor laser device according to claim 1, further comprising second mirrors different from the mirror, the second mirrors being separately reflecting a plurality of pieces of the laser light emitted from the semiconductor laser element in a direction orthogonal to the emitted laser light in an in-plane direction of a plane along the surface of the substrate.

5. The semiconductor laser device according to claim 4, wherein the second mirrors are columnar bodies forming a triangle with an angle of 45 degrees when viewed from a front side of the substrate.

6. The semiconductor laser device according to claim 4 or 5, wherein surfaces of the second mirrors are provided with an Al coating film.

7. A semiconductor laser device comprising:
a substrate;
a semiconductor laser element in which a plurality of laser light sources for emitting laser light in a longitudinal direction of the substrate are disposed in parallel;
third mirrors in a triangular prism shape that are disposed to face the laser light sources and reflect the laser light emitted from the laser light sources in an in-plane direction of a plane along a surface of the substrate and in a direction not perpendicular to the emitted laser light;
a fourth mirror that is disposed at an end of the laser light sources, has surfaces inclined at an angle other than 45 degrees with respect to the substrate in a truncated square pyramid shape or in a polygonal pyramid shape, and reflects the laser light reflected by the third mirrors in a direction perpendicular to the surface of the substrate; and
a lens disposed adjacent to the fourth mirror and disposed on a side where the laser light reflected by the fourth mirror travel.

8. The semiconductor laser device according to claim 7, wherein an Al coating film is provided on surfaces of the third mirrors.

9. (canceled)

10. A method for manufacturing the semiconductor laser device according to claim 1, wherein the semiconductor laser device includes a submount, and the semiconductor laser element is die-bonded and mounted on the submount by a junction down method.

11. The semiconductor laser device according to claim 2, wherein the mirror has a truncated square pyramid shape or a polygonal pyramid shape and has surfaces inclined at 45 degrees with respect to the substrate.

12. The semiconductor laser device according to claim 3, further comprising second mirrors different from the mirror, the second mirrors being separately reflecting a plurality of pieces of the laser light emitted from the semiconductor laser element in a direction orthogonal to the emitted laser light in an in-plane direction of a plane along the surface of the substrate.

13. The semiconductor laser device according to claim 12, wherein the second mirrors are columnar bodies forming a triangle with an angle of 45 degrees when viewed from a front side of the substrate.

14. The semiconductor laser device according to claim 5, wherein surfaces of the second mirrors are provided with an Al coating film.

15. The semiconductor laser device according to claim 12, wherein surfaces of the second mirrors are provided with an Al coating film.

16. The semiconductor laser device according to claim 13, wherein surfaces of the second mirrors are provided with an Al coating film.

17. A method for manufacturing the semiconductor laser device according to claim 7, wherein the semiconductor laser device includes a submount, and the semiconductor laser element is die-bonded and mounted on the submount by a junction down method.
